(19) United States
(12) Patent Application Publication
(10) Pub. No.: US 2013/0077449 A1
(43) Pub. Date: Mar. 28, 2013

(54) TERMINAL CONNECTING STRUCTURE FOR ELECTRONIC COMPONENT, PACKAGE, PIEZOELECTRIC VIBRATOR, OSCILLATOR, ELECTRONIC INSTRUMENT, AND RADIO TIMEPIECE

(71) Applicant: Seiko Instruments Inc., Chiba (JP)

(72) Inventor: Kiyoshi ARATAKE, Chiba (JP)

(73) Assignee: SEIKO INSTRUMENTS INC., Chiba (JP)

(21) Appl. No.: 13/627,704

(22) Filed: Sep. 26, 2012

(30) Foreign Application Priority Data
Sep. 27, 2011 (JP) 2011-211216

(51) Int. Cl. H01L 41/047; H03B 1/00; G04C 11/02; H05K 1/09

(52) U.S. Cl. 368/47; 174/257; 310/364; 331/156

(57) ABSTRACT

To provide a terminal connecting structure for an electronic component which achieves prevention of an increase in the electric resistance value between a through electrode and an electrode connected thereto and ensuring preferable conductive performance, a package, a piezoelectric vibrator, an oscillator, an electronic instrument, and a radio timepiece having a substrate of this terminal connecting structure for the electronic component. There is provided a terminal connecting structure for an electronic component including; a through electrode penetrating through a base substrate: and an external electrode electrically connected to the through electrode, wherein an outer end surface of the through electrode is formed with a coating film of a conductive oxide which covers the outer end surface, and the through electrode and the external electrode are electrically connected via the film of the conductive oxide.

### RELATED APPLICATIONS

This application claims priority under 35 U.S.C. §119 to Japanese Patent Application No. 2011-211216 filed on Sep. 27, 2011, the entire content of which is hereby incorporated by reference.

### TECHNICAL FIELD

The present invention relates to a terminal connecting structure for an electronic component, a package, a piezoelectric vibrator, an oscillator, an electronic instrument, and a radio timepiece.

### DESCRIPTION OF THE RELATED ART

In recent years, a piezoelectric vibrator using crystal or the like is employed in mobile phones or portable information terminal as a timing source or a reference signal source of a time-of-day source or a control signal. Various types of the piezoelectric vibrators of this type are known, and as one of these piezoelectric vibrators, a two-layer type surface-mounted piezoelectric vibrator is known.

The two-layer type piezoelectric vibrator is packaged by bonding a first substrate and a second substrate directly, and a piezoelectric vibration reed is accommodated in a cavity formed between the both substrates. Known examples of the two-layer structure type piezoelectric vibrators as described above include a piezoelectric vibrator including a through electrode which conducts electricity between the inside and outside of the first substrate, and an external electrode electrically connected to an external electrode formed on the outside of the first substrate.

Various methods are proposed as methods of forming the through electrode on the first substrate of the piezoelectric vibrator of this type.

For example, in JP-A-2002-124845, a method of forming a through electrode by forming a through hole in a base substrate and driving in a metallic pin in the through hole in a state in which the base substrate is softened by heat is described.

There is also a known method of forming a through electrode by forming a through hole in a base substrate, disposing a metallic pin in the through hole, filling a gap between the through hole and the metallic pin with glass frit, and fixing the metallic pin by hardening the glass fit.

As a method of forming an external electrode, a method of applying conductive paste such as silver paste on a mask formed with an opening at a position corresponding to the position of a through electrode, which is so-called screen printing, is also known. The external electrode is formed so as to cover an end surface of the through electrode by drying and solidifying the conductive paste applied on the end surface of the through electrode.

Incidentally, the end surface of the through electrode is exposed from the surface of the base substrate until the external electrode is formed. Therefore, the end surface of the through electrode is easily oxidized in the process of manufacture, and hence there arises a problem in that an insulative oxidized film is readily formed. When the through electrode is formed so as to cover the end surface of the through electrode in a state in which the insulative oxidized film is formed, since the insulative oxidized film is interposed between the end surface of the through electrode and the external electrode, there is a risk of increase in an electric resistance value.

Accordingly, formation of the insulative oxidized film on the end surface of the through electrode is prevented by, for example, applying gold plating on the end surface of the through electrode. Then, increase in the electric resistance value between the end surface of the through electrode and the external electrode is inhibited by forming the external electrode on the end surface of the through electrode by interposing the gold plate.

However, the gold plate generally presents low adhesiveness with respect to other metals. Therefore, when the external electrode is formed on the end surface of the through electrode by the intermediary of the gold plate, the external electrode may separate from the through electrode, and hence the conduction failure may occur. In particular, since the gold plate presents low adhesiveness with respect to silver, this problem becomes prominent if an external electrode is formed of silver paste.

### SUMMARY

Accordingly, it is an object of the invention to provide a terminal connecting structure for an electronic component which achieves prevention of an increase in the electric resistance value between a through electrode and an electrode connected thereto and ensuring preferable conductive performance, a package, a piezoelectric vibrator, an oscillator, an electronic instrument, and a radio timepiece having a substrate of this terminal connecting structure for the electronic component.

In order to solve the above-described object, there is provided a terminal connecting structure for an electronic component including; a through electrode penetrating through a substrate: and an electrode electrically connected to the through electrode, wherein an end surface of the through electrode is formed with a film of a conductive oxide which covers the end surface, and the through electrode and the electrode are electrically connected via the film of the conductive oxide.

According to the invention, formation of an insulative oxidized film on the end surfaces of the through electrodes may be prevented by forming the film of the conductive oxide on the end surfaces of the through electrodes. Therefore, since the insulative oxidized film is not interposed between the through electrodes and the electrodes, the through electrodes and the electrodes may be electrically connected while preventing the increase in the electric resistance value between the through electrodes and the electrodes.

Since the through electrodes and the electrodes are electrically connected via the film of the conductive oxide, desirable adhesiveness may be secured between the through electrodes and the electrodes. Therefore, separation of the electrodes from the through electrodes may be restrained, and hence the desirable conductive performance may be secured between the through electrodes and the electrodes.

Preferably, the conductive oxide is formed of any one of ITO, SnO, and SnO₂.

According to the invention, the film is formed on the end surface of the through electrode using ITO, SnO, and SnO₂, so that preferable adhesiveness between the through electrode and the electrode may be secured.

Preferably, the electrode is formed of silver paste.

According to the invention, the electrode is preferably formed of silver paste, so that the desirable adhesiveness between the through electrode and the electrode is achieved.

A package of the invention includes the substrate having the terminal connecting structure of the electronic component described above, and is capable of sealing an electronic element, wherein the electrode is an external electrode formed on the outside of the substrate, a film of the conductive oxide for covering the end surface is formed on an outer end surface of the through electrode, and the through electrode and the external electrode are electrically connected via the film of the conducive oxide.

According to the invention, formation of an insulative oxidized film on the end surface of the through electrode may be prevented by forming the film of the conductive oxide on the outer end surfaces of the through electrodes. Therefore, since the insulative oxidized film is not interposed between the through electrodes and the external electrodes, and the through electrodes and the external electrodes may be electrically connected while preventing increase in the electric resistance value between the through electrodes and the external electrodes.

Since the through electrodes and the external electrodes are electrically connected via the film of the conductive oxide, desirable adhesiveness is achieved between the through electrodes and the external electrodes. Therefore, separation of the external electrodes from the through electrodes may be restrained, and hence the preferable conductive performance may be secured between the through electrodes and the external electrodes.

Preferably, the surface area of the film of the conductive oxide is set to be larger than the surface area of the outer end surface of the through electrode.

Also, according to the invention, a larger contact surface area is secured between the film of the conductive oxide and the external electrodes more than a case where the film of the conductive oxide is formed only on the outer end surfaces of the through electrodes by setting the surface area of the film of the conductive oxide larger than the surface areas of the outer end surfaces of the through electrodes. Accordingly, since the electrical resistance value between the through electrodes and the external electrodes may be inhibited to a lower level, the better preferable conductive performance is secured between the through electrodes and the external electrodes.

Preferably, the piezoelectric vibration reed is sealed in the interior of the above-described package as the electronic element.

According to the invention, since the piezoelectric vibration reed is sealed in the interior of the package which is capable of securing the preferable conductive performance between the through electrodes and the external electrodes while preventing the increase in the electric resistance value between the through electrodes and the external electrodes, the piezoelectric vibrator having desirable performance and higher efficiency is provided.

According to the invention, there is provided an oscillator wherein the piezoelectric vibrator described above is electrically connected to an integrated circuit as an oscillator.

According to the invention, there is provided an electronic instrument wherein the piezoelectric vibrator described above is electrically connected to a clocking unit.

According to the invention, there is provided a radio timepiece wherein the piezoelectric vibrator described above is electrically connected to a filter unit.

According to the oscillator, the electronic instrument and the radio wave of the invention, the oscillator, the electronic instrument, and the radio timepiece having desirable performances and high efficiencies are provided.

According to the invention, formation of the insulative oxidized film on the end surfaces of the through electrodes is prevented by forming the film of the conductive oxide on the end surfaces of the through electrodes. Therefore, since the insulative oxidized film is not interposed between the through electrodes and the electrodes, the through electrodes and the electrodes may be electrically connected while preventing increase in the electric resistance value between the through electrodes and the electrodes.

Since the through electrodes and the electrodes are electrically connected via the film of the conductive oxide, desirable adhesiveness is secured between the through electrodes and the electrodes. Therefore, separation of the electrodes from the through electrodes may be restrained, and hence the preferable conductive performance is secured between the through electrodes and the electrodes.

### BRIEF DESCRIPTION OF THE DRAWINGS

FIG. 1 is a perspective view showing an appearance of a piezoelectric vibrator;

FIG. 2 is a plan view showing an internal configuration of the piezoelectric vibrator shown in FIG. 1 in a state in which a lid substrate is removed;

FIG. 3 is a cross-sectional view taken along the line A-A in FIG. 2;

FIG. 4 is an exploded perspective view of the piezoelectric vibrator shown in FIG. 1;

FIG. 5 is an explanatory drawing showing a connecting structure between a through electrode and an external electrode;

FIG. 6 is a flowchart showing a method of manufacturing the piezoelectric vibrator;

FIG. 7 is an exploded perspective view of a wafer member;

FIG. 8 is an explanatory drawing showing a coating film forming process;

FIG. 9 is a drawing showing a configuration of an embodiment of an oscillator;

FIG. 10 is a drawing showing a configuration of an embodiment of an electronic apparatus; and

FIG. 11 is a drawing showing a configuration of an embodiment of a radio timepiece.

### DESCRIPTION OF THE PREFERRED EMBODIMENTS

### (Piezoelectric Vibrator)

Referring now to the drawings, a piezoelectric vibrator according to an embodiment of the invention will he described.

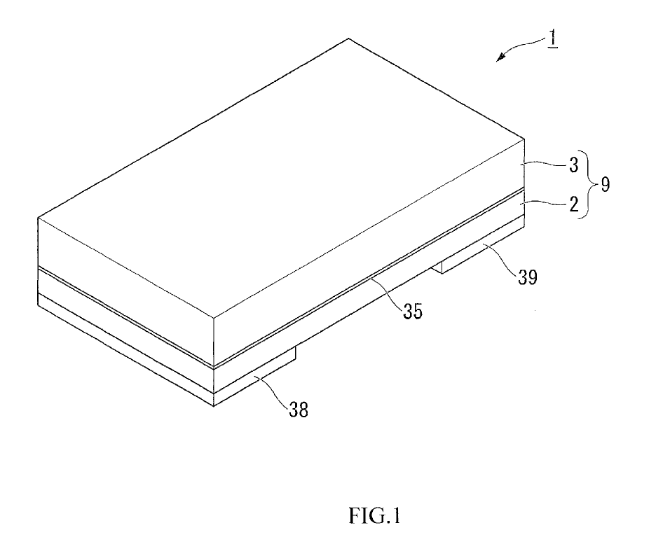

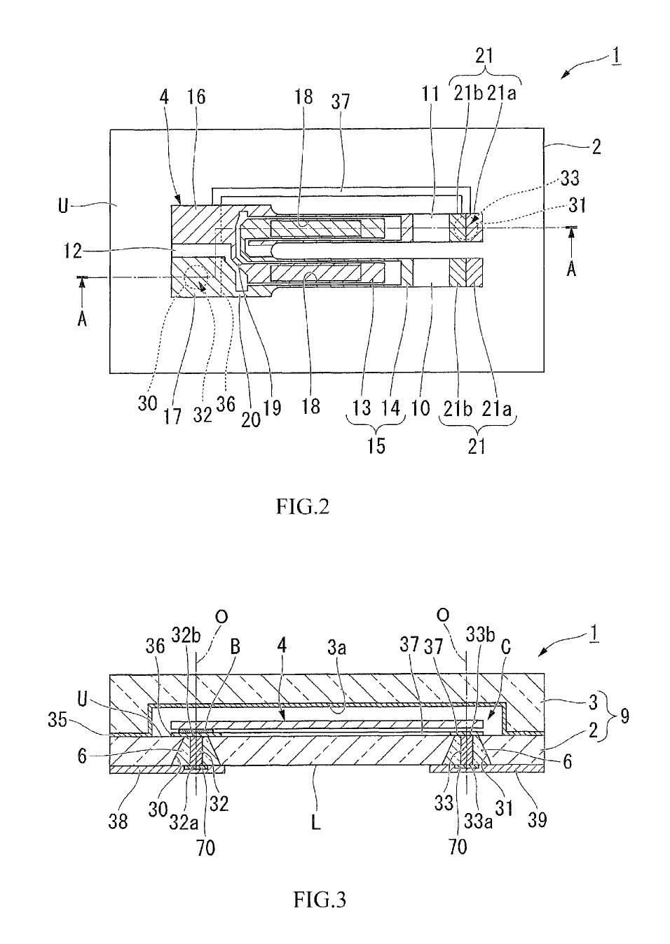

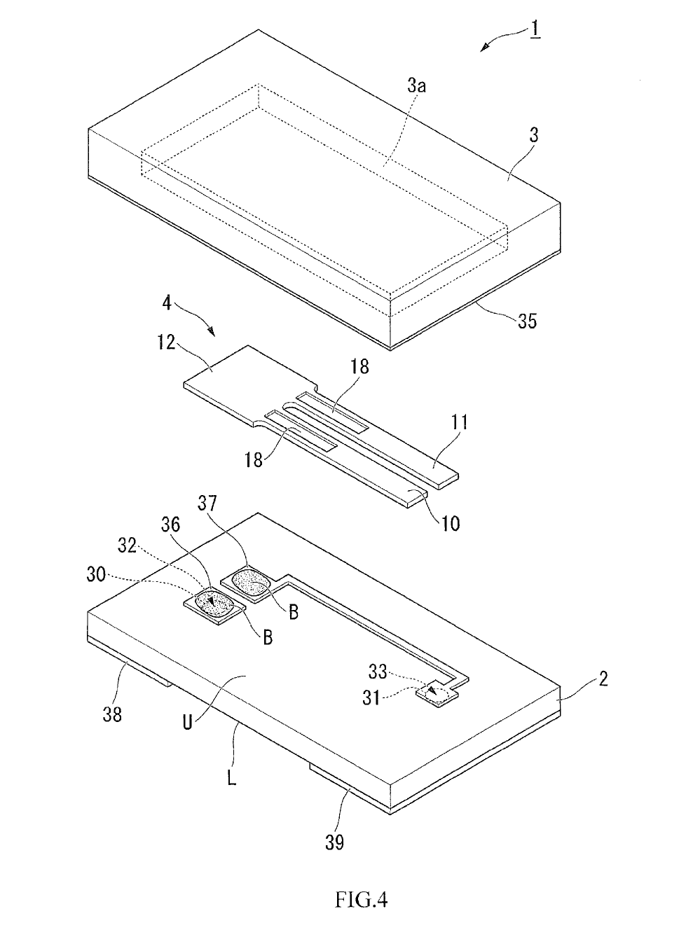

FIG. 1 is a perspective view of an appearance of a piezoelectric vibrator 1 (which corresponds to an “electronic component” in Claims), FIG. 2 is an internal configuration drawing of the piezoelectric vibrator 1; and FIG. 3 is a cross-sectional view taken along the line A-A in FIG. 2. FIG. 4 is an exploded perspective view of the piezoelectric vibrator 1 shown in FIG. 1.

In the description given below, an outer surface of a base substrate 2 is expressed as an outer surface L, and an inner surface of the base substrate 2 is expressed as an inner surface U. In FIG. 4, illustration of an excitation electrode 15, drawn electrodes 19 and 20, mount electrodes 16 and 17, and weight metal films 21 described later will be omitted for facilitating understanding of the drawing.

As shown in FIG. 1, the piezoelectric vibrator 1 in this embodiment is a package 9 formed by anodic wafer bonding of the base substrate 2 and a lid substrate 3 via a bonding film 35, and is the surface-mounted piezoelectric vibrator 1. As shown in FIG. 3, a piezoelectric vibration reed 4 (which corresponds to an “electronic element” in Claims) is accommodated in a cavity C in the interior of the package 9.

### (Piezoelectric Vibration Reed)

As shown in FIG. 2, the piezoelectric vibration reed 4 is a turning-fork-type vibration reed formed of a piezoelectric material such as crystal, lithium tantalate, or lithium niobate, and is configured to vibrate when a predetermined voltage is applied. The piezoelectric vibration reed 4 includes a pair of vibrating arm portions 10 and 11 arranged in parallel, a base member 12 integrally fixing proximal end sides of the pair of vibrating arm portions 10 and 11, and groove portions 18 formed on both main surfaces of the pair of vibrating arm portions 10 and 11. The groove portions 18 are formed from the proximal end sides to portions near substantially mid sections of the vibrating arm portions 10 and 11 along the longitudinal direction of the vibrating arm portions 10 and 11.

Excitation electrodes 13 and 14 and the drawn electrodes 19 and 20 are each formed with a monolayer film of chrome, which is the same material as base layers of the mount electrodes 16 and 17, described later. Accordingly, film formation of the excitation electrodes 13 and 14 and the drawn electrodes 19 and 20 may be performed simultaneously with the film formation of the basic layers of the mount electrodes 16 and 17.

The excitation electrodes 13 and 14 are electrodes which vibrate the pair of vibrating arm portions 10 and 11 at a predetermined resonance frequency in the direction toward and away from each other. The first excitation electrodes 13 and the second excitation electrodes 14 are formed by being patterned on an outer surfaces of the pair of vibrating arm portions 10 and 11 in a state of being electrically disconnected respectively.

The mount electrodes 16 and 17 arc laminated films including chrome and gold, and are each formed by forming a chrome layer presenting good adhesiveness with respect to crystal as a base layer and then forming a gold thin layer on the surface thereof as a top layer.

The pair of vibrating aim portions 10 and 11 are coated with the weight metal films 21 for adjusting the vibrating states of themselves to fall within a range of a predetermined frequency (frequency adjustment) at distal ends thereof. The weight metal film 21 includes a coarse adjustment film 21a used for roughly adjusting the frequency and a fine adjustment film 21b used for finely adjusting the frequency. By adjusting the frequency using the coarse adjustment films 21a and the fine adjustment films 21b, the frequencies of the pair of vibrating arm portions 10 and 11 may be adjusted to a range of the nominal frequency of a device.

### (Package)

As shown in FIG. 1, the base substrate 2 and the lid substrate 3 are anodically bondable substrates formed of a glass material, for example, a soda-lime glass, and is formed into a substantially plate shape. As shown in FIG. 3, a cavity depression 3a configured to accommodate the piezoelectric vibration reed 4 is formed on the side of a bonding surface of the lid substrate 3 with respect to the base substrate 2.

The entire surface of the lid substrate 3 on the side of the bonding surface with respect to the base substrate 2 is formed with the bonding film 35 for an anodic wafer bonding. In other words, the bonding film 35 is formed into a frame area around the cavity depression 3a in addition to the entire inner surface of the cavity depression 3a. Although the bonding film 35 in this embodiment is formed of a silicone film, the bonding film 35 may be formed of aluminum, chrome, or the like. The bonding film 35 and the base substrate 2 are bonded by the anodic wafer bonding, and the cavity C is vacuumized and sealed.

### (Through Electrode)

The piezoelectric vibrator 1 penetrates through the base substrate 2 in the thickness direction and includes through electrodes 32 and 33 which conducts electricity between the inner surface U of the base substrate 2 and the outer surface L of the base substrate 2. The through electrodes 32 and 33 are arranged in through holes 30 and 31 penetrating through the inner surface U of the base substrate 2 and the outer surface L of the base substrate 2, and electrically connecting the piezoelectric vibration reed 4 and external electrodes 38 and 39, described later.

As shown in FIG. 2, the through holes 30 and 31 are formed so as to be accommodated in the cavity C when the piezoelectric vibrator 1 is formed. More specifically, the through holes 30 and 31 are such that the one through hole 30 is formed at a position corresponding to the base portion 12 of the piezoelectric vibration reed 4 mounted thereon in a mounting process described later and the other through hole 31 is formed at a position corresponding to the distal end sides of the vibrating arm portions 10 and 11.

As shown in FIG. 3, the through electrodes 32 and 33 are arranged along central axes 0 of the through holes 30 and 31.

The through electrodes 32, 33 are conductive rod-shaped members formed of a metallic material such as silver, nickel alloy, or aluminum, and is molded by forging or press work. The through electrodes 32 and 33 preferably formed of metal having a coefficient of linear expansion close to that of glass material of the base substrate 2, for example, alloy containing 58 weight percent of iron and 42 weight percent of nickel (42 alloy). Outer end surfaces 32a and 33a of the through electrodes 32 and 33 are electrically connected to the external electrodes 38 and 39, described later. Inner end surface 32b and 33b of the through electrodes 32 and 33 are electrically connected to drawing electrodes 36 and 37, described later.

Glass members 6 are filled in gaps between the through holes 30 and 31 and the through electrodes 32 and 33.

The glass members 6 are formed by sintering glass frit, and are secured firmly with respect to outer surfaces of the through electrodes 32 and 33 and inner peripheral surfaces of the through holes 30 and 31. The glass members 6 completely close the gaps between the through holes 30 and 31 and the through electrodes 32 and 33, and maintains air-tightness in the cavity C.

### (Coating Film of Conductive Oxide)

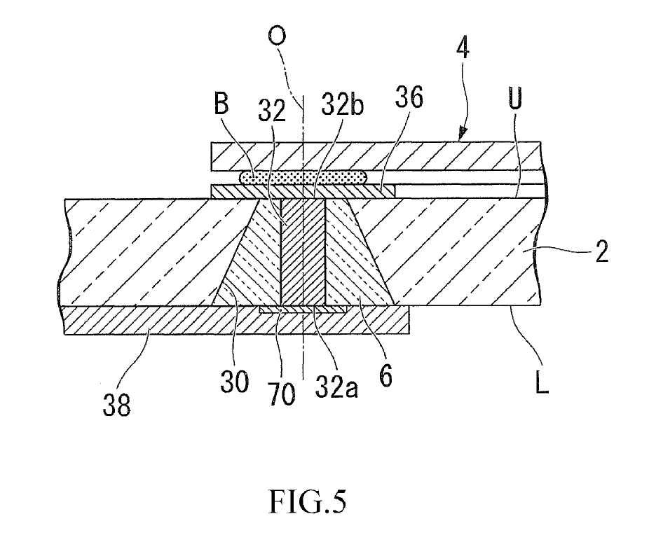

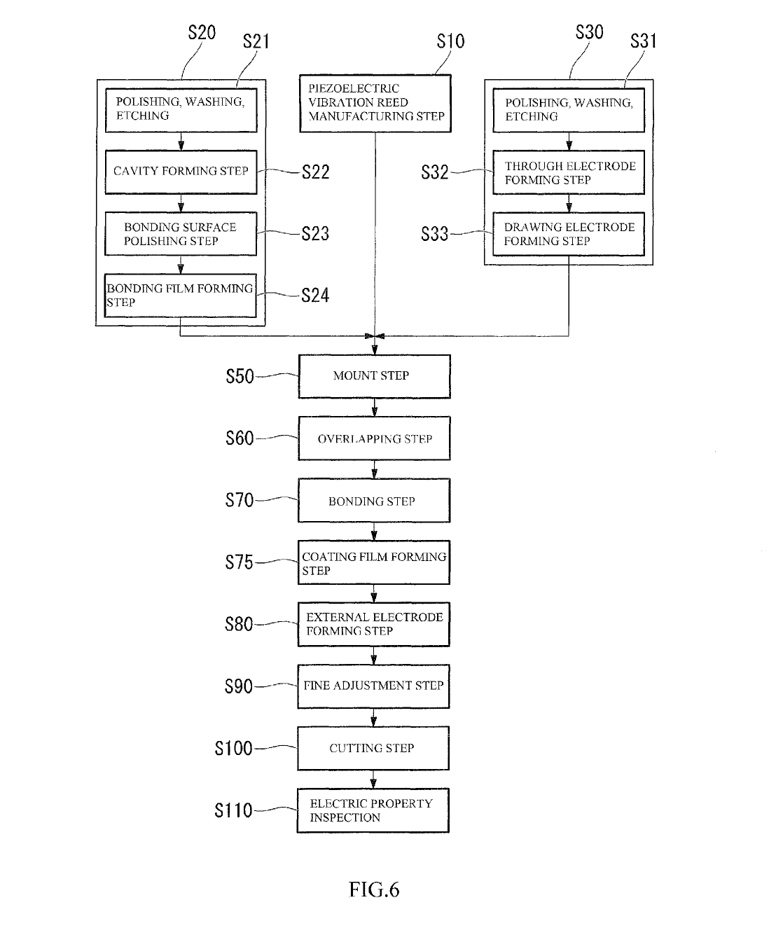

FIG. 5 is an explanatory drawing showing a connecting structure between the through electrode 32 and the external electrode 38. The connecting structure between the through electrode 32 and the external electrode 38 and the connecting structure between the through electrode 33 and the external electrode 39 are the same. Therefore, in the description with reference to FIG. 5 given below, the connecting structure between the through electrode 32 the external electrode 38 will be described, and description of the connecting structure between the through electrode 33 and the external electrode 39 will be omitted.

As shown in FIG. 5, the outer end surface 32a exposed from the outer surface L of the base substrate 2 from among end surfaces of the through electrode 32 is formed with a coating film 70 so as to cover the outer end surface 32a.

The coating film 70 is formed of the conductive oxide such as ITO (indium tine oxide), SnO, SnO₂ (both are oxidized silicon) as a material, and is formed to have a film thickness on the order of 1000 angstrom.

The coating film 70 covers the entire surface of the outer end surface 32a of the through electrode 32 when viewed from the direction of the central axis O of the through electrode 32, further covers part of the glass member 6, and is formed so as to be larger than the outline of the outer end surface 32a. In other words, the surface area of the coating film 70 viewed from the direction of the central axis O is set to be larger than the surface area of the outer end surface 32a of the through electrode 32.

### (External Electrode)

As shown in FIG. 3, the outer surface L of the base substrate 2 is formed with a pair of the external electrodes 38 and 39 which cover the coating film 70 at both end portions of the base substrate 2 on the longitudinal direction.

The external electrodes 38 and 39 are formed by applying the conductive material such as silver paste, and then drying and solidifying the same. The external electrodes 38 and 39 are electrically connected to the through electrodes 32 and 33 via the coating film 70. Here, the conductive oxide such as ITO, SnO, and SnO₂ presents desirable adhesiveness with respect to silver. Therefore, the through electrodes 32 and 33 and the external electrodes 38 and 39 are firmly connected via the coating film 70.

As shown in FIG. 4, a pair of the drawing electrodes 36 and 37 are patterned on the side of the inner surface U of the base substrate 2. The drawing electrodes 36 and 37 are films formed of gold or the like for example, and are formed, for example, by a spattering method or a CVD method.

The drawing electrode 36 of the pair of drawing electrodes 36 and 37 is formed so as to be positioned right above the inner end surface 32b of the through electrode 32. The other drawing electrode 37 is drawn from a position adjacent to the one drawing electrode 36 along the vibrating arm portions 10 and 11 to distal end sides of the vibrating arm portions 10 and 11, and then is formed so as to be positioned right above the inner end surface 33b of the other through electrode 33.

Then, bumps B are formed respectively on the pair of drawing electrodes 36 and 37 and a pair of the mount electrodes 16 and 17 of the piezoelectric vibration reed 4 are mounted using the bumps B. Accordingly, the mount electrode 17 of the piezoelectric vibration reed 4 is in conduction with the through electrode 32 via the drawing electrode 36, and the mount electrode 16 is in conduction with the through electrode 33 via the drawing electrode 37 (see FIG. 2).

When activating the piezoelectric vibrator 1 configured in this manner, a predetermined drive voltage is applied to the external electrodes 38 and 39 formed on the base substrate 2. Accordingly, since a voltage may be applied to the excitation electrodes 15 including the first excitation electrodes 13 and the second excitation electrodes 14 of the piezoelectric vibration reed 4, the pair of vibrating arm portions 10 and 11 may be vibrated in the direction toward and away from each other at a predetermined frequency. Then, the piezoelectric vibrator 1 may be used as a time-of-day source, a timing source of a control signal, a reference signal source, or the like using the vibrations of the pair of vibrating arm portions 10 and 11.

### (Method of Manufacturing Piezoelectric Vibrator)

FIG. 6 is a flowchart showing a method of manufacturing the piezoelectric vibrator 1 in this embodiment.

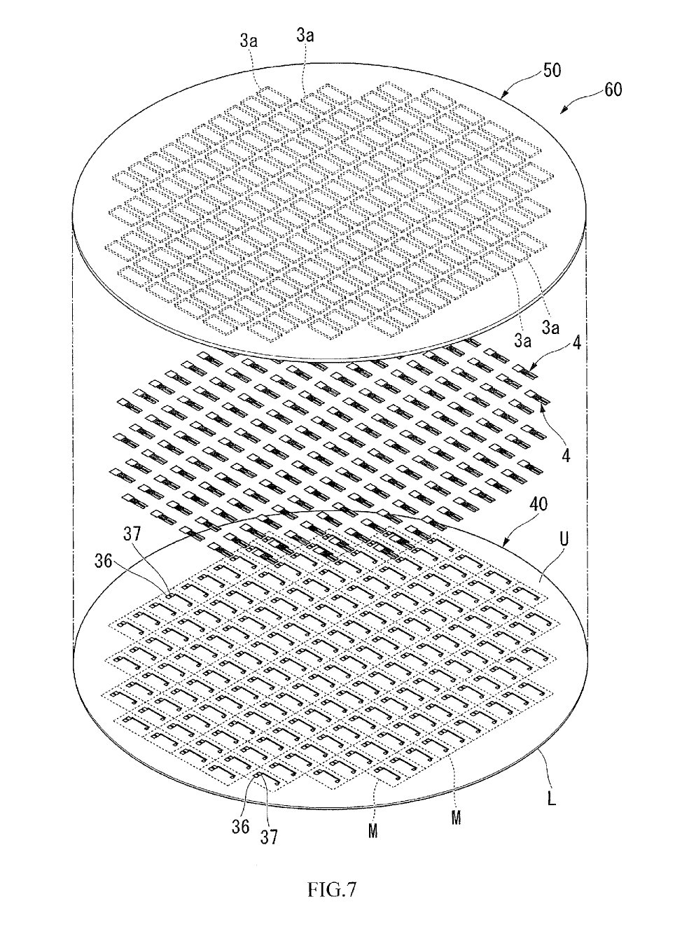

FIG. 7 is an exploded perspective view of a wafer member 60. Dot lines shown in FIG. 7 indicate cutting lines M to be cut in a cutting process performed later.

Subsequently, the method of manufacturing the piezoelectric vibrator 1 will be described with reference to a flowchart in FIG. 6.

As shown in FIG. 6, the method of manufacturing the piezoelectric vibrator 1 in this embodiment includes a piezoelectric vibration reed manufacturing step S10, a lid substrate wafer manufacturing step S20, a base substrate wafer manufacturing step S30, and an assembling step (from mount step S50 onward). The piezoelectric vibration reed manufacturing step 510, the lid substrate wafer manufacturing step S20, and the base substrate wafer manufacturing step S30 from among the respective steps may be performed in parallel.

### (Piezoelectric Vibration Reed Manufacturing Step)

In the piezoelectric vibration reed manufacturing step S10, the piezoelectric vibration reeds 4 are manufactured. More specifically, firstly, Lambert raw stone of crystal is sliced at a predetermined angle, and a mirror polishing process such as polishing is performed, so that a wafer having a predetermined thickness is obtained. Subsequently, patterning of outlines of the piezoelectric vibration reeds 4 is performed by photolithography technique, and film formation and patterning of metallic film are performed, so that the excitation electrodes 13 and 14, the drawn electrodes 19 and 20, the mount electrodes 16 and 17, and the weight metal films 21 are formed. Subsequently, coarse adjustment of the resonance frequency of the piezoelectric vibration reeds 4 is performed. With the procedure described above, the piezoelectric vibration reed manufacturing step S10 is terminated.

### (Lid Substrate Wafer Manufacturing Step)

In the lid substrate wafer manufacturing step S20, a lid substrate wafer 50 which will become the lid substrate 3 later is manufactured. First of all, the disk-shaped lid substrate wafer 50 formed of soda lime grass is cleaned by polishing process to a predetermined thickness, and then an affected flow layer of a topmost surface is removed by etching or the like (S21). Subsequently, in a cavity forming step S22, a plurality of the cavity depressions 3a are formed on the lid substrate wafer 50 on a bonding surface with respect to a base substrate wafer 40. Formation of the cavity depressions 3a is performed by hot-press molding or etching process. Subsequently, in a bonding surface polishing step S23, the bonding surface with respect to the base substrate wafer 40 is polished.

Subsequently, in a bonding film forming step S24, the bonding film 35 (see FIG. 3) is formed on the bonding surface with respect to the base substrate wafer 40. The formation of the bonding film 35 is achieved by film forming methods such as spattering method or CVD method. With the procedure described above, the lid substrate wafer manufacturing step S20 is terminated.

### (Base Substrate Wafer Manufacturing Step)

In the base substrate wafer manufacturing step, a base substrate wafer 40 which will become the base substrate 2 later is manufactured. First of all, the disk-shaped base substrate wafer 40 formed of soda lime grass is cleaned by polishing process to a predetermined thickness, and then an affected flow layer of a topmost surface is removed by etching or the like (S31).

### (Through Electrode Forming Step)

Subsequently, a through electrode forming step S32 for forming a pair of the through electrodes 32 and 33 is performed on the base substrate wafer 40. Although the description of the step of forming the through electrode 32 will be given below, the step of forming the through electrode 33 is also the same.

First of all, the through holes 30 are molded from the outer surface L to the inner surface U of the base substrate wafer 40. Then, the through electrodes 32 are inserted into the through holes 30 and fill glass frit therein. The glass frit mainly includes powdered glass particles, organic solvent, and binder (securing agent).

Subsequently, the glass frit is sintered to form the glass members 6, and the glass members 6, the through holes 30, and the through electrodes 32 are unified (see FIG. 3). For example, the glass frit is sintered after the base substrate wafer 40 has been transported into a sintering furnace. At this time, the organic solvent and the binder in the interior of the glass frit are evaporated, so that out gas containing carbon monoxide (CO), carbon dioxide (CO,), and water vapor (H₂O) is generated, and is discharged out from the glass frit.

Finally, the inner end surfaces 32b of the through electrodes 32 are exposed from the inner surface U by polishing the inner surface U and the outer surface L of the base substrate wafer 40 into a flat surface, so that the outer end surfaces 32a of the through electrodes 32 are exposed from the outer surface L. The through electrodes 32 secure conductive property between the inner surface U side and the outer surface L side of the base substrate wafer 40 and, simultaneously, the through holes 30 of the base substrate wafer 40 are sealed.

### (Drawing Electrode Forming Step)

Subsequently, a drawing electrode forming step S33 for forming the plurality of drawing electrodes 36 and 37 electrically connected respectively to the through electrodes 32 and 33 on the inner surface U of the base substrate wafer 40 is performed. Then, the bumps B formed of gold or the like (see FIG. 4) are formed on the drawing electrodes 36 and 37. In FIG. 7, illustration of the bumps B is omitted for the sake of easy-to-understand. At this time point, the base substrate wafer manufacturing step S30 is terminated.

### (Mount Step)

Subsequently, a mount step S50 for bonding the piezoelectric vibration reeds 4 via the bumps B on the drawing electrodes 36 and 37 of the base substrate wafer 40 is performed. More specifically, the base members 12 of the piezoelectric vibration reeds 4 are placed on the bumps B, the bumps B are heated to a predetermined temperature and, at the same time, ultrasonic vibrations are applied while pressing the piezoelectric vibration reeds 4 against the bumps B. Accordingly, as shown in FIG. 3, the base members 12 are mechanically secured to the bumps B in a state in which the vibrating arm portions 10 and 11 of the piezoelectric vibration reeds 4 are apart upward from the inner surface U of the base substrate wafer 40.

### (Overlapping Step)

After the mounting of the piezoelectric vibration reeds 4 has terminated, an overlapping step (S60) for overlapping the lid substrate wafer 50 on the base substrate wafer 40 is performed. With this step, the piezoelectric vibration reeds 4 mounted on the base substrate wafer 40 are brought into a state of being accommodated in the cavities C surrounded by the cavity depressions 3a of the lid substrate wafer 50 and the base substrate wafer 40.

### (Bonding Step)

After the overlapping step S60, the overlapped both wafers 40 and 50 are put into an anode bonding apparatus, not shown, and a bonding step S70 for applying a predetermined voltage in a predetermined temperature atmosphere for anode bonding is performed. In this process, the piezoelectric vibration reeds 4 may be sealed in the cavities C, and the wafer member 60 shown in FIG. 7 including the base substrate wafer 40 and the lid substrate wafer 50 bonded to each other will be obtained. In FIG. 7, for the sake of easy-to-understand of the drawing, a state in which the wafer member 60 is exploded is shown, and illustration of the bonding film 35 is omitted from the lid substrate wafer 50.

### (Coating Film Forming Step)

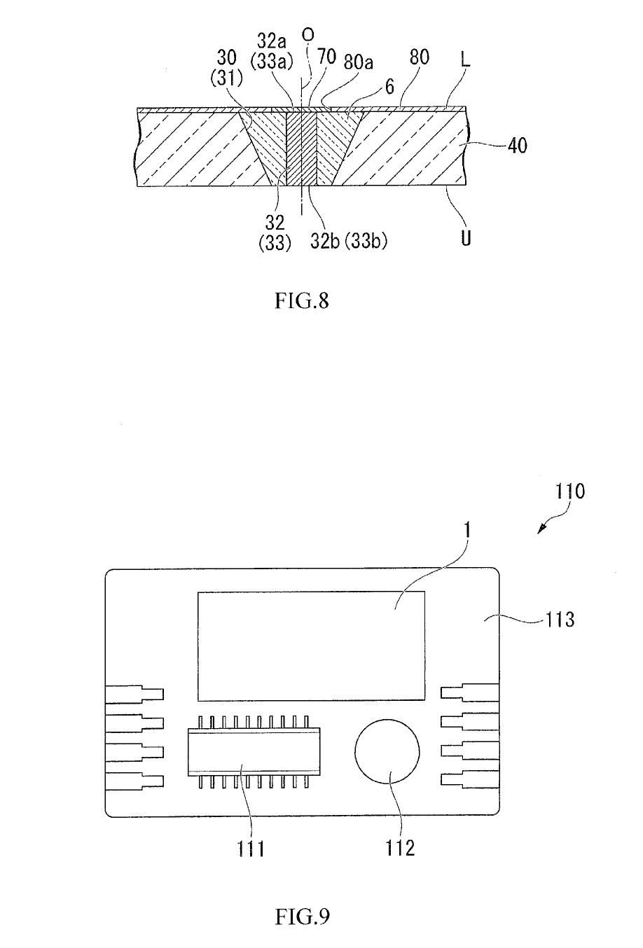

FIG. 8 is an explanatory drawing of a coating film forming step S75, and is a cross-sectional side view of the base substrate wafer 40.

Subsequently, a coating film forming step S75 for forming the coating film 70 formed of the conductive oxide such as ITO, SnO, and SnO₂ on the outer end surfaces 32a and 33a of the through electrodes 32 and 33 exposed from the outer surface L of the base substrate wafer 40 is preformed.

In the coating film forming step S75, a mask material 80 having openings 80a corresponding to areas for forming the through electrodes 32 and 33 is arranged in abutment with the outer surface L of the base substrate wafer 40. Then, by a film forming method such as the spatter method, the CDV method, or vacuum deposition method, the conductive oxide is applied from the side of the outer surface L via the mask material 80 to form the coating film 70. The coating film 70 is formed to have a thickness on the order of 1000 angstrom, for example.

Here, the openings 80a of the mask material 80 are formed to be larger than the outer shape of the outer end surfaces 32a and 33a of the through electrodes 32 and 33 when viewed from the direction of the central axes O of the through electrodes 32 and 33. Accordingly, the coating film 70 covers the entire surfaces of the outer end surfaces 32a and 33a of the through electrodes 32 and 33, then covers part of the glass member 6, and is formed so as to be larger than the surface area of the outer end surface 32a.

### (External Electrode Forming Step)

Subsequently, an external electrode forming step S80 for patterning silver paste on the outer surface L of the base substrate wafer 40, and forming a plurality of the pairs of external electrodes 38 and 39 (see FIG. 3) electrically connected respectively to the pair of through electrodes 32 and 33 is performed. More specifically, a mask, not shown, formed with openings at positions corresponding to the positions where the external electrodes 38 and 39 are arranged in abutment with the outer surface L of the base substrate wafer 40, and the silver paste is applied via the mask by, for example, screen printing. With this step, the through electrodes 32 and 33 are formed so as to be electrically connected with the external electrodes 38 and 39 via the through electrodes 32 and 33 and the coating film 70. Then, the piezoelectric vibration reeds 4 in the cavities C are brought into conduction with the external electrodes 38 and 39 via the through electrodes 32 and 33 and the coating film 70.

### (Fine Adjustment Step)

Subsequently, a fine adjustment step S90 for fine-adjusting the frequencies of the individual piezoelectric vibrators sealed in the cavities C in the state of the wafer member 60 is performed. With this step, the frequency of the piezoelectric vibrator is adjusted within the range of the nominal frequency.

### (Cutting Process)

After the fine-adjustment of the frequency is terminated, a cutting process S100 for cutting the bonded wafer member 60 along the cutting lines M shown in FIG. 7 is preformed. Accordingly, the wafer member 60 is separated into a plurality of the piezoelectric vibrators 1.

### (Electric Property Inspection)

Subsequently, an electric property inspection S110 for the interior is performed. In other words, the resonance frequency or the resonance resistance, drive level properties (dependency of the resonance frequency and the resonance resistance value on the exciting electricity) or the like of the piezoelectric vibration reeds 4 are measured and checked. The insulating resistant property or the like are also checked. Then, finally, the appearance inspection of the piezoelectric vibrator is performed to finally check the dimensions and quality. The manufacture of the piezoelectric vibrators is now terminated.

### (Effects)

According to this embodiment, formation of the insulative oxidized film on the outer end surfaces 32a and 33a of the through electrodes 32 and 33 is prevented by forming the coating film 70 of the conductive oxide on the outer end surfaces 32a and 33a of the through electrodes 32 and 33. Therefore, since the insulative oxidized film is not interposed between the through electrodes 32 and 33 and the external electrodes 38 and 39, the through electrodes 32 and 33 and the external electrodes 38 and 39 may be electrically connected while preventing increase in the electric resistance value between the through electrodes 32 and 33 and the external electrodes 38 and 39.

Since the through electrodes 32 and 33 and the external electrodes 38 and 39 are electrically connected via the coating film 70 of the conductive oxide, desirable adhesiveness between the through electrodes 32 and 33 and the external electrodes 38 and 39 is secured. Therefore, separation of the external electrodes 38 and 39 from the through electrodes 32 and 33 may be restrained, and hence the preferable conductive performance is secured between the through electrodes 32 and 33 and the external electrodes 38 and 39.

Also, according to the embodiment, a larger contact surface area is secured between the coating film 70 of the conductive oxide and the external electrodes 38 and 39 more than a case where the coating film 70 of the conductive oxide is formed only on the outer end surfaces 32a and 33a of the through electrodes 32 and 33 by setting the surface area of the coating film 70 of the conductive oxide larger than the surface areas of the outer end surfaces 32a and 33a of the through electrodes 32 and 33. Accordingly, since the electrical resistance value between the through electrodes 32 and 33 and the external electrodes 38 and 39 may be inhibited to a lower level, the better preferable conductive performance is secured between the through electrodes 32 and 33 and the external electrodes 38 and 39.

According to the embodiment, since the piezoelectric vibration reed 4 is sealed in the interior of the package 9 which secures the preferable conductive performance between the through electrodes 32 and 33 and the external electrodes 38 and 39 while preventing increase in the electric resistance value between the through electrodes 32 and 33 and the external electrodes 38 and 39, the piezoelectric vibrator 1 having desirable performance and higher efficiency is provided.

### (Oscillator)

Subsequently, an embodiment of an oscillator according to the invention will be described with reference to FIG. 9.

An oscillator 110 in this embodiment includes the piezoelectric vibrator 1 configured as an oscillator electrically connected to an integrated circuit 111 as shown in FIG. 9. The oscillator 110 includes a substrate 113 on which an electronic element component 112 such as a capacitor is mounted. The substrate 113 includes the integrated circuit 111 described above for the oscillator mounted thereon, and the piezoelectric vibration reed of the piezoelectric vibrator 1 is mounted in the vicinity of the integrated circuit 111. The electronic element component 112, the integrated circuit 111, and the piezoelectric vibrator 1 are electrically connected respectively by a wiring pattern, not shown. The respective components are molded by a resin, not shown.

In the oscillator 110 configured in this manner, when a voltage is applied to the piezoelectric vibrator 1, the piezoelectric vibration reed 4 in the piezoelectric vibrator 1 vibrates. Such vibrations are converted into an electric signal by the piezoelectric property of the piezoelectric vibration reed 4, and is input to the integrated circuit 111 as an electric signal. The input electric signal is subjected to various processes by the integrated circuit 111 and is output as a frequency signal. Accordingly, the piezoelectric vibrator 1 functions as an oscillator.

In addition, by setting the configuration of the integrated circuit 111, for example, by selectively setting an RTC (Real Time Clock) module or the like according to the request, in addition to the function of a single-function oscillator for a time piece, a function to control the date and time of operation of the single-function oscillator for a time piece or external instruments or a function to provide the time of day or a calendar may be added.

According to the oscillator 110 in the embodiment, since the piezoelectric vibrator 1 having high performance and high efficiency is provided, the oscillator 110 having desirable performance and high efficiency is provided.

### (Electronic Instrument)

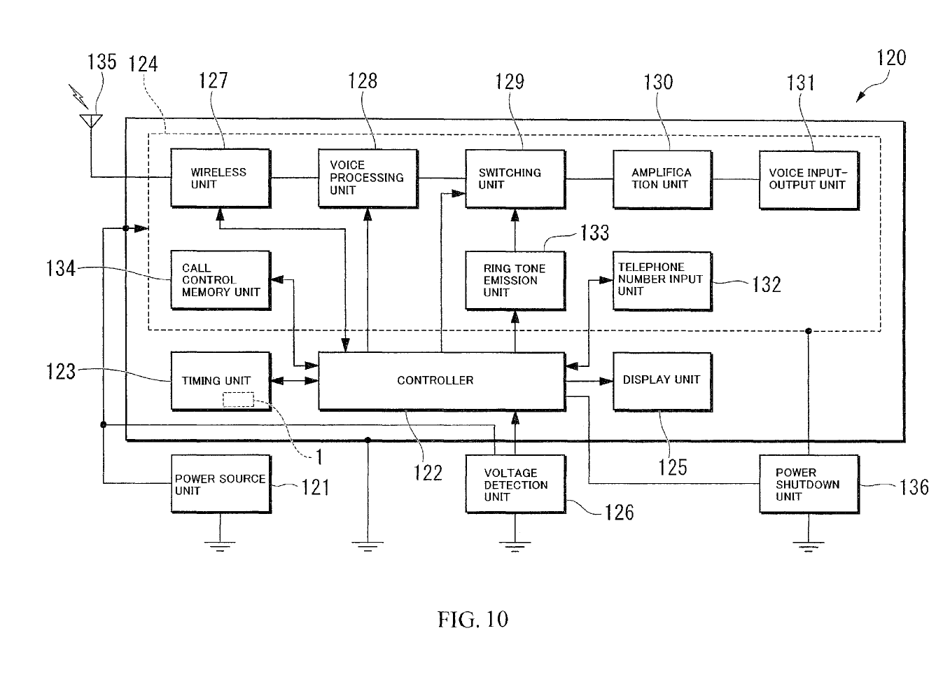

Referring now to FIG. 10, an embodiment of an electronic instrument according to the invention will be described. A portable digital assistant device 120 having the piezoelectric vibrator 1 described above as the electronic instrument will be described as an example. First of all, the portable digital assistant device 120 in this embodiment is represented, for example, by a mobile phone, which is a developed and improved wrist watch of the related art. An appearance is similar to the wrist watch, including a liquid crystal display at a portion corresponding to a dial, which is configured to display current time or the like on a screen thereof. When used as a communication instrument, the same communication as the mobile phone of the related art may be performed by removing the same from the wrist and using a speaker and a microphone integrated in a potion inside a band. However, downsizing and reduction in weight are dramatically achieved in comparison with the mobile phone of the related art.

Subsequently, a configuration of the portable digital assistant device 120 of the embodiment will be described. The portable digital assistant device 120 includes the piezoelectric vibrator 1 and a power source unit 121 configured to supply power as shown in FIG. 10. The power source unit 121 is formed of, for example, a lithium secondary cell. The power source unit 121 includes a control unit 122 configured to perform various types of control, a clocking unit 123 configured to count time of day or the like, a communication unit 124 configured to perform communication with the outside, a display unit 125 configured to display various items of information, and a voltage detection unit 126 configured to detect voltage of the respective functional portions connected in parallel to each other. Then, the power is supplied to the respective functional portions by the power source unit 121.

The control unit 122 controls the operation of the entire system, such as controlling the respective functional portions to perform sending and receiving of voice data, and counting and display of the current time-of-day. The control unit 122 includes a ROM in which a program is written in advance, a CPU configured to read out the program written in the ROM, and a RAM used as a work area for the CPU.

The clocking unit 123 includes an integrated circuit having an oscillation circuit, a register circuit, a counter circuit, and an interface circuit integrated therein, and the piezoelectric vibrator 1. When a voltage is applied to the piezoelectric vibrator 1, the piezoelectric vibration reed vibrates, and the vibrations thereof is converted into an electric signal by the piezoelectric property of crystal, and is input to the oscillation circuit as the electric signal. The output from the oscillation circuit is binarized and is counted by the register circuit and the counter circuit. Then, sending and receiving of the signal with respect to the control unit 122 are performed via the interface circuit, and the current time of day, the current date, calendar information, or the like are displayed on the display unit 125.

The communication unit 124 has the same function as the mobile phones of the related art, and includes a wireless unit 127, a voice processing unit 128, a switch unit 129, an amplifying unit 130, a voice input/output unit 131, a phone number input unit 132, a ring tone generating unit 133, and a call control memory unit 134.

The wireless unit 127 performs sending and receiving of various types of data such as voice data with respect to a base station via an antenna 135. The voice processing unit 128 codes and decodes the voice signal input from the wireless unit 127 or the amplifying unit 130. The amplifying unit 130 amplifies the signal input from the voice processing unit 128 or the voice input/output unit 131 to a predetermined level. The voice input/output unit 131 includes a speaker or a microphone, or the like, and is configured to amplify a ringtone or a receiving voice, or collect a voice.

The ring tone generating unit 133 generates the ringtone according to a call from the base station. The switch unit 129 switches the amplifying unit 130 connected to the voice processing unit 128 to the ring tone generating unit 133 only at the time of incoming call, so that the ringtone generated by the ring tone generating unit 133 is output to the voice input/output unit 131 via the amplifying unit 130.

The call control memory unit 134 stores a program relating to control of incoming and outgoing call of communication. The phone number input unit 132 includes, for example, numerical keys from 0 to 9 and other keys, and is configured to input a telephone number of the called party by pushing these numerical keys or the like.

The voltage detection unit 126 detects voltage drop when the voltage applied to the receptive functional portions such as the control unit 122 by the power source unit 121 becomes lower than a predetermined value, and notifies the same to the control unit 122. The predetermined voltage value at this time is a value preset as a minimum required voltage for keeping a stable operation of the communication unit 124 and, for example, on the order of 3 V. The control unit 122 which receives the notification of the voltage drop from the voltage detection unit 126 prohibits the wireless unit 127, the voice processing unit 128, the switch unit 129, and the ring tone generating unit 133 from operating. In particular, the stop of the operation of the wireless unit 127 which consumes a large amount of power is essential. Then, the fact that the communication unit 124 is disabled due to insufficient remaining battery power is displayed on the display unit 125.

In other words, the operation of the communication unit 124 is prohibited by the voltage detection unit 126 and the control unit 122, and that effect may be displayed on the display unit 125. This display may be made by messages including characters. However, as more intuitive display, a cross mark (x) may be shown on a phone icon displayed on an upper portion of a display surface of the display unit 125.

With the provision of a power source blocking unit 136 which is capable of selectively blocking the electric power of a portion relating to the function of the communication unit 124, the function of the communication unit 124 may be stopped further reliably.

According to the portable digital assistant device 120 in the embodiment, since the piezoelectric vibrator 1 having desirable performance and high efficiency is provided, the portable digital assistant device 120 having desirable performance and high efficiency is provided.

### (Radio Timepiece)

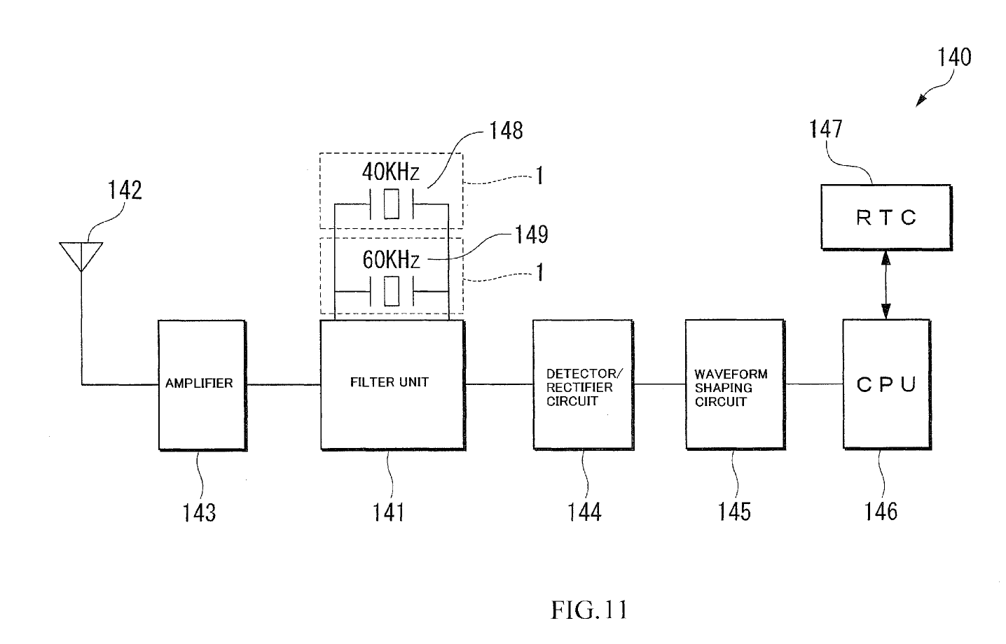

Referring now to FIG. 11, an embodiment of a radio timepiece according to the invention will be described.

A radio timepiece 140 in this embodiment includes the piezoelectric vibrator 1 electrically connected to a filter portion 141 as shown in FIG. 11, and is a timepiece having a function to receive standard radio waves including timepiece information and display correct time of day automatically corrected.

In Japan, there are transmitting stations (transmitter stations) which transmit the standard radio waves in Fukushima prefecture (40 kHz) and Saga prefecture (60 kHz), and transmit respective standard radio waves. Since long waves such as 40 kHz or 60 kHz have both a property to propagate the ground surface and a property to propagate while being reverberate between an ionization layer and the ground surface, a wide range of the propagation is achieved, so that the above-described two transmitting stations cover entire part of Japan.

Hereinafter, a functional configuration of the radio timepiece 140 will be described in detail.

An antenna 142 receives a long-wave standard radio wave of 40 kHz or 60 kHz. A long-wave standard radio wave is time information referred to as a time code subjected to an AM modulation to a carrier wave of 40 kHz or 60 kHz. The long-wave standard radio wave is amplified by an amplifier 143 and is filtered and synchronized by the filter portion 141 having the plurality of piezoelectric vibrators 1.

The piezoelectric vibrators 1 in this embodiment include quartz vibrator units 148 and 149 having resonant frequencies of 40 kHz and 60 kHz which are the same as the above-described carrier frequencies, respectively.

In addition, a signal filtered and having a predetermined frequency is subjected to detection and demodulation by a detection and rectification circuit 144.

Subsequently, the time code is acquired via a waveform shaping circuit 145, and is counted by a CPU 146. The CPU 146 reads information such as the current year, day of year, day of the week, and time-of-day. The read information is reflected on an RTC 147, and a correct time of day information is displayed.

Since the carrier wave has 40 kHz or 60 kHz, vibrators having the above-described tuning-fork type structure is suitable for the quartz vibrator units 148, 149.

The above-described description is based on an example in Japan, and the frequency of the long standard radio waves are different in foreign countries. For example, in Germany a standard radio wave of 77.5 kHz is used. Therefore, when integrating the radio timepiece 140 which is compatible with foreign countries in the portable apparatuses, another piezoelectric vibrator 1 having a frequency different from that in Japan is required.

According to the radio timepiece 140 in the embodiment, since the piezoelectric vibrator 1 having high performance and high efficiency is provided, the radio timepiece 140 having preferable performance and high efficiency is provided.

The technical scope of the invention is not limited to the embodiments shown above, and various modifications may be made without departing the scope of the invention.

In the embodiment, the piezoelectric vibrator 1 using the tune-fork type piezoelectric vibration reed 4 is exemplified for describing the package 9 and the method of manufacturing the package 9. However, for example, the package 9 of the invention described above and the method of manufacturing the package described above may be employed for the piezoelectric vibrator using the piezoelectric vibration reed (thickness-shear mode vibration reed) of an AT cut type.

In this embodiment, the piezoelectric vibrator 1 is manufacture by sealing the piezoelectric vibration reed 4 in the interior of the package 9 according to the invention. However, devices other than the piezoelectric vibrator 1 may be manufactured by sealing the electronic elements other than the piezoelectric vibration reed 4 in the interior of the package 9.

In this embodiment, the surface area of the coating film 70 of the conductive oxide is set to be larger than the surface areas of the outer end surfaces 32a and 33a of the through electrodes 32 and 33. However, the surface areas of the coating film 70 may be set to be the same as those of the outer end surfaces 32a and 33a of the through electrodes 32 and 33 by covering only the outer end surfaces 32a and 33a of the through electrodes 32 and 33. However, the embodiment is competitive in that larger contact surface areas between the coating film 70 of the conductive oxide and the external electrodes 38 and 39 may be secured, and the electric resistance value between the coating film 70 of the conductive oxide and the external electrodes 38 and 39 may be inhibited to a lower level.

1. A terminal connecting structure for an electronic component, the connecting structure comprising:
a through electrode penetrating through a substrate;
an electrode electrically connected to the through electrode; and
a conductive oxide film on an end surface of the through electrode that covers the end surface,
wherein the through electrode and the electrode are electrically connected by the conductive oxide film.

2. The terminal connecting structure according to claim 1, wherein the conductive oxide film comprises one of ITO, SnO, or SnO₂.

3. The terminal connecting structure according to claim 1, wherein the electrode comprises a silver paste.

4. The terminal connecting structure according to claim 1, wherein an area of the conductive oxide film is larger than a surface area of the outer end surface of the through electrode.

5. A package sealing an electronic element, the package comprising:
a substrate
a through electrode penetrating through the substrate;
an external electrode on an outside surface of the substrate and electrically connected to the through electrode; and
a conductive oxide film covering an outer end surface of the through electrode,
wherein the through electrode and the external electrode are electrically connected by the conducive oxide film.

6. The package according to claim 5, wherein an area of the conductive oxide film is larger than a surface area of the outer end surface of the through electrode.

7. The package according to claim 5, wherein the conductive oxide film comprises one of ITO, SnO, or SnO₂.

8. The package according to claim 5, wherein the external electrode comprises a silver paste.

9. The package according to claim 5, wherein the electronic element comprises a piezoelectric vibration reed.

10. An oscillator comprising the piezoelectric vibration reed of claim 9, wherein the piezoelectric vibration reed is electrically connected to an integrated circuit.

11. An electronic instrument comprising the piezoelectric vibration reed of claim 9, wherein the piezoelectric vibration reed is electrically connected to a clocking unit.

12. A radio timepiece comprising the piezoelectric vibration reed of claim 9, wherein the piezoelectric vibration reed is electrically connected to a filter unit.
